(19) United States
(12) Patent Application Publication
(10) Pub. No.: US 2021/0391156 A1
(43) Pub. Date: Dec. 16, 2021

(54) CLEAN UNIT FOR CHAMBER EXHAUST CLEANING

(71) Applicant: Applied Materials, Inc., Santa Clara, CA (US)

(72) Inventors: Kelvin Chan, San Ramon, CA (US); Philip Allan Kraus, San Jose, CA (US); Thai Cheng Chua, Cupertino, CA (US); Hanh Nguyen, San Jose, CA (US); Anantha Subramani, San Jose, CA (US)

(21) Appl. No.: 16/898,244

(22) Filed: Jun. 10, 2020

(51) Int. Cl. H01J 37/32; B08B 7/00; H05H 1/46

(52) U.S. Cl. CPC H01J 37/32862; B08B 7/0035; C23C 16/4405; H01J 37/32449; H05H 1/46

(57) ABSTRACT

Embodiments disclosed herein include a cleaning module for the exhaust line of a chamber. In an embodiment, a mobile cleaning module comprises a chamber where the chamber comprises a first opening and a second opening. In an embodiment, the cleaning module further comprises a lid to seal the first opening. In an embodiment, the lid comprises a dielectric plate, a dielectric resonator coupled to the dielectric plate, a monopole antenna positioned in a hole into the dielectric resonator, and a conductive layer surrounding the dielectric resonator.

### BACKGROUND

### 1) Field

Embodiments relate to vacuum chambers, and more particular to cleaning units for chamber exhausts.

### 2) Description of Related Art

In semiconductor manufacturing, chamber processes may result in unwanted deposits in the exhaust line. The unwanted deposits can accumulate over time and negatively affect tool performance. For example, this accumulation may cause the exhaust line conductance to reduce and/or the components along the exhaust line to fail. The throttle valve in the exhaust line is particularly susceptible to such accumulations.

Currently, there is no solution for cleaning the deposits from the throttle valve or other components of the exhaust line. The only remedy currently available is replacement of the throttle valve. Replacing the throttle valve requires significant down time for the processing tool, and is therefore a costly maintenance.

### SUMMARY

Embodiments disclosed herein include a cleaning module for the exhaust line of a chamber. In an embodiment, a mobile cleaning module comprises a chamber where the chamber comprises a first opening and a second opening. In an embodiment, the cleaning module further comprises a lid to seal the first opening. In an embodiment, the lid comprises a dielectric plate, a dielectric resonator coupled to the dielectric plate, a monopole antenna positioned in a hole into the dielectric resonator, and a conductive layer surrounding the dielectric resonator.

An additional embodiment disclosed herein includes a mobile cleaning assembly for the exhaust line of a chamber. In an embodiment, the mobile cleaning assembly comprises a cart, and a solid state electronics module on the cart, where the solid state electronics module is configured to generate microwave electromagnetic radiation. In an embodiment, the assembly further comprises a processor on the cart and electrically coupled to the solid state electronics module, and a plasma cleaning module. In an embodiment, the plasma cleaning module is electrically coupled to the solid state electronics module.

An additional embodiment disclosed herein includes a processing tool with a cleaning module on an exhaust line. In an embodiment, the processing tool comprises a first chamber with a pedestal for supporting a substrate, and an exhaust line fluidically coupled to the first chamber. In an embodiment, the exhaust line comprises a pump, a main exhaust line between the first chamber and the pump, a throttle valve positioned in the main exhaust line, and a cleaning line fluidically coupled to the main exhaust line. In an embodiment, a second chamber is fluidically coupled to the cleaning line, and a plasma source is provided for generating a plasma in the second chamber.

The above summary does not include an exhaustive list of all embodiments. It is contemplated that all systems and methods are included that can be practiced from all suitable combinations of the various embodiments summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

FIG. 1A is a cross-sectional illustration of a processing tool that comprises a plasma cleaning module coupled to the exhaust, in accordance with an embodiment.

FIG. 1B is a cross-sectional illustration of a processing tool that comprises a modular microwave plasma source and a plasma cleaning module coupled to the exhaust, in accordance with an embodiment.

FIG. 2 is a block diagram of solid state electronics for generating microwave electromagnetic radiation, in accordance with an embodiment.

FIG. 3A is a cross-sectional illustration of a plasma cleaning module, in accordance with an embodiment.

FIG. 3B is a cross-sectional illustration of a plasma cleaning module with a dielectric plate and a dielectric resonator that are a monolithic structure, in accordance with an embodiment.

FIG. 3C is a cross-sectional illustration of a plasma cleaning module with a conductive layer surrounding the dielectric resonator that comprises multiple layers, in accordance with an embodiment.

FIG. 3D is a cross-sectional illustration of a plasma cleaning module with a plurality of dielectric resonators, in accordance with an embodiment.

FIG. 4A is a cross-sectional illustration of an exhaust with an integrated plasma cleaning module, in accordance with an embodiment.

FIG. 4B is a cross-sectional illustration of an exhaust with a portable plasma cleaning module, in accordance with an embodiment.

FIG. 5A is a block diagram of a mobile cleaning assembly, in accordance with an embodiment.

FIG. 5B is a block diagram of a mobile cleaning assembly, in accordance with an additional embodiment.

FIG. 6 is a process flow diagram of a process for using a cleaning module to clean an exhaust line, in accordance with an embodiment.

FIG. 7 illustrates a block diagram of an exemplary computer system that may be used in conjunction with a plasma cleaning module, in accordance with an embodiment.

### DETAILED DESCRIPTION

Devices in accordance with embodiments described herein include a cleaning unit for a chamber exhaust line. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, accumulation of deposits in the exhaust line requires expensive down time for the processing tool. Accordingly, embodiments disclosed herein include a plasma cleaning module that is attached to the exhaust line. The plasma cleaning module may provide a plasma species that cleans the exhaust line. As such, the plasma cleaning module can remove the deposits without needing to take the processing tool off-line for a significant amount of time. Particularly, the processing tool may remain under vacuum during cleaning, so that re-evacuating the processing tool and re-establishing stable conditions for substrate processing are not necessary following the maintenance. This is a significant cost savings.

In some embodiments, the plasma cleaning module is portable. That is, the plasma cleaning module may be part of a mobile cleaning assembly that may be shared between multiple chambers. This reduces the capital costs needed to provide the cleaning functionality. Additionally, the processing tools may not need sufficient redesign to accommodate the plasma cleaning module. The plasma cleaning module may connect to a port along the exhaust line.

A portable plasma cleaning module is possible due to the design of the plasma source. Particularly, embodiments disclosed herein include a microwave plasma source with solid state electronics. The use of such a microwave source allows for a compact design compared to magnetron microwave power sources, which require bulky waveguides. In embodiments disclosed herein, the solid state electronics module may be stored on a cart and attached to a dielectric resonator of the portable cleaning module by a coaxial cable. In an embodiment, the cart may also house a gas panel and a cooling source that are also attached to the portable cleaning module. However, one or both of the gas and cooling fluid may also be sourced from the processing tool in some embodiments.

Additionally, due to the compact design of the plasm cleaning module, the plasma cleaning module may be integrated with the processing tool. That is, the plasma cleaning module may be considered part of the processing tool. In such embodiments, gas and cooling fluid may be sourced from the processing tool.

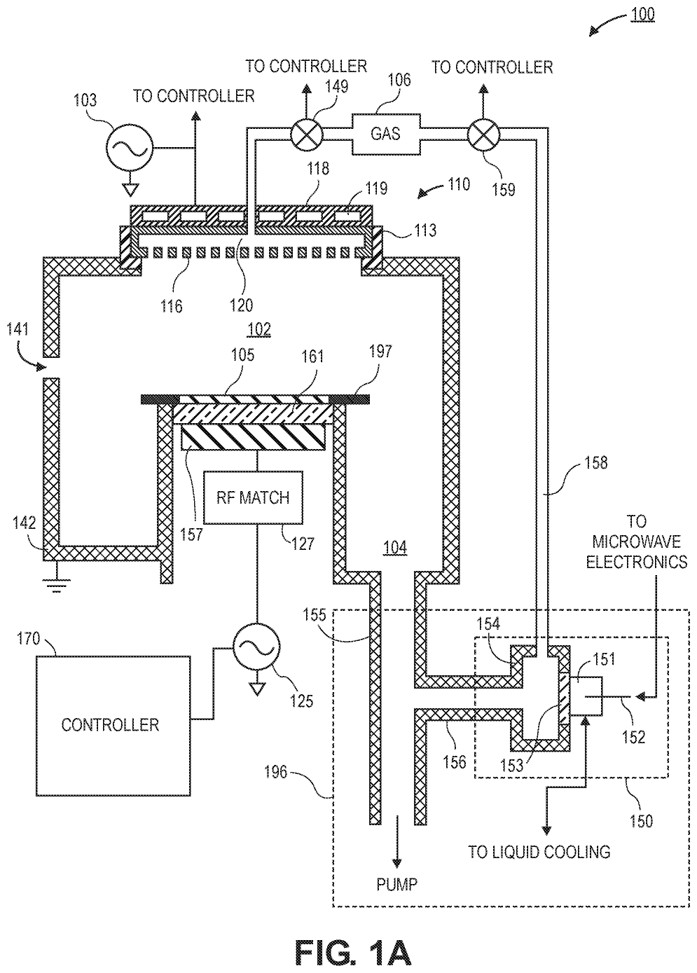

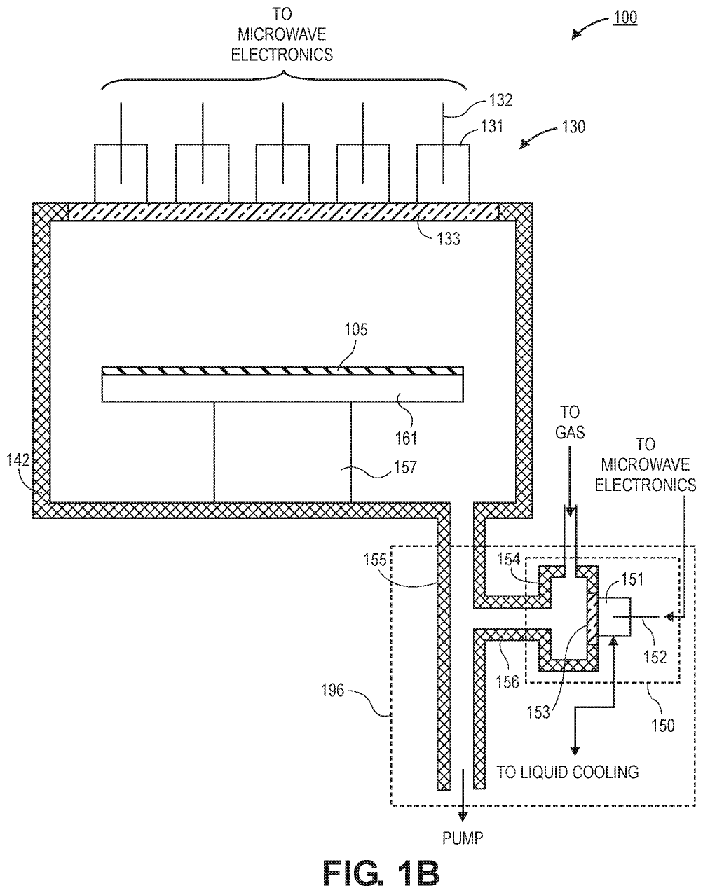

Referring now to FIG. 1, a cross-sectional illustration of a processing tool 100 that comprises a plasma cleaning module 150 is shown, in accordance with an embodiment. The plasma processing tool 100 may be a plasma etch chamber, a chemical vapor deposition chamber, a plasma enhanced chemical vapor deposition chamber, an atomic layer deposition chamber, a plasma enhanced atomic layer deposition chamber, a physical vapor deposition chamber, a plasma treatment chamber, an ion implantation chamber, or other suitable vacuum or controlled environment processing chamber.

Processing tool 100 includes a grounded chamber 142. The chamber 142 may comprise a processing region 102 and an evacuation region 104. The chamber 142 may be sealed with a lid assembly 110. Process gases are supplied from one or more gas sources 106 (e.g., a gas panel) through a mass flow controller 149 to the lid assembly 110 and into the processing region 102.

A pump in the exhaust region 196 may maintain a desired pressure within the chamber 142 and remove byproducts from processing in the chamber 142. In an embodiment, the exhaust region may comprise an exhaust line 155 that is between the chamber 142 and the pump. A cleaning line 156 may intersect the exhaust line 155. In an embodiment, the cleaning line 156 is between the exhaust line 155 and a plasma cleaning module 150. In an embodiment, the plasma cleaning module is configured to provide a remote plasma for cleaning the exhaust region 196.

In an embodiment, the plasma cleaning module 150 comprises a cleaning chamber 154. The cleaning chamber 154 is where the plasma is generated. In an embodiment, the cleaning chamber 154 comprises a first opening that is sealed by a dielectric plate 153, and a second opening that connects to the cleaning line 156. The plasma in the plasma cleaning module 150 may be generated using a modular microwave source. For example, a dielectric resonator 151 is coupled to the dielectric plate 153. A monopole antenna 152 is inserted into an axial center of the dielectric resonator 151. The monopole antenna 152 is connected to solid state microwave generating electronics (described in greater detail below). Due to the solid state design, bulky waveguides and other components needed for magnetron style microwave plasmas are not needed and a compact design is provided. The compact design allows for the plasma cleaning module 150 to be integrated with the processing tool without significant redesign.

In an embodiment, the plasma cleaning module 150 is connected to the gas source 106 by gas line 158. A mass flow controller 159 may control the flow of gas into the cleaning chamber 154. In the illustrated embodiment, the gas line 158 is shown passing through a wall of the cleaning chamber 154. However, it is to be appreciated that the gas may also be supplied through the dielectric plate 153 (e.g., using a showerhead design or other manifold type structure). In an embodiment, the plasma cleaning module 150 may also be temperature controlled. For example, the plasma cleaning module 150 may be connected to a source of cooling fluid.

In an embodiment, the lid assembly 110 generally includes an upper electrode comprising a showerhead plate 116 and a heat transfer plate 118. The lid assembly 110 is isolated from the chamber 142 by an insulating layer 113. The upper electrode is coupled to a source RF generator 103 through a match (not shown). Source RF generator 103 may have a frequency between 300 kHz and 60 MHz or between 60 MHz and 180 MHz, for example, and in a particular embodiment, is in the 13.56 MHz band.

Accordingly, the processing tool 100 may comprise a pair of plasma sources. For example, the RF generator 103 may generate a first plasma in the processing region 102, and the microwave electronics may generate a second plasma in the cleaning chamber 154. In the particular embodiment illustrated in FIG. 1A, the first plasma and the second plasma are generated with different wavelengths of electromagnetic radiation.

The gas from the gas source 106 enters into a manifold 120 within the showerhead plate 116 and exits into processing region 102 of the chamber 142 through openings into the showerhead plate 116. In an embodiment, the heat transfer plate 118 comprises channels 119 through which heat transfer fluid is flown. The showerhead plate 116 and the heat transfer plate 118 are fabricated from an RF conductive material, such as aluminum or stainless steel. In certain embodiments, a gas nozzle or other suitable gas distribution assembly is provided for distribution of process gases into the chamber 142 instead of (or in addition to) the showerhead plate 116.

The processing region 102 may comprise a lower electrode 161 onto which a substrate 105 is secured. Portions of a process ring 197 that surrounds the substrate 105 may also be supported by the lower electrode 161. The substrate 105 may be inserted into (or extracted from) the chamber 142 through a slit valve tunnel 141 through the chamber 142. A door for the slit valve tunnel 141 is omitted for simplicity. The lower electrode 161 may be an electrostatic chuck. The lower electrode 161 may be supported by a support member 157. In an embodiment, lower electrode 161 may include a plurality of heating zones, each zone independently controllable to a temperature set point. For example, lower electrode 161 may comprise a first thermal zone proximate a center of substrate 105 and a second thermal zone proximate to a periphery of substrate 105. Bias power RF generator 125 is coupled to the lower electrode 161 through a match 127. Bias power RF generator 125 provides bias power, if desired, to energize the plasma. Bias power RF generator 125 may have a low frequency between about 300 kHz to 60 MHz for example, and in a particular embodiment, is in the 13.56 MHz band.

In FIG. 1A, the processing tool 100 is shown as being a plasma reactor that is capable of forming a plasma in the processing region 102. However, it is to be appreciated that the processing tool 100 may include a processing region 102 that does not utilize a plasma source. For example, the processing tool 100 may comprise a furnace. In some embodiments, the processing region 102 may also be a batch reactor. That is, the processing region 102 may process a plurality of substrates at the same time.

Referring now to FIG. 1B, a cross-sectional illustration of a processing tool 100 is shown, in accordance with an additional embodiment. The processing tool in FIG. 1B may be substantially similar to the processing tool 100 in FIG. 1A, with the exception of the plasma source 130 for generating a plasma in the processing region 102. Instead of using an RF plasma source, the processing tool 100 in FIG. 1B may utilize a microwave plasma source 130. In a particular embodiment, the microwave plasma source 130 is a modular microwave plasma source. For example, the microwave plasma source 130 may comprise a dielectric plate 133 with a plurality of dielectric resonators 131 arranged over the dielectric plate 133. A monopole antenna 131 may be disposed in an axial center of each dielectric resonator 131. The monopole antennas 131 may each be connected to solid state microwave generating electronics.

In one embodiment, the solid state microwave electronics of the microwave plasma source 130 may be the same microwave electronics used for plasma generation in the plasm cleaning module 150. In other embodiments, separate microwave electronics may be used for the microwave plasma source 130 and the plasma cleaning module 150.

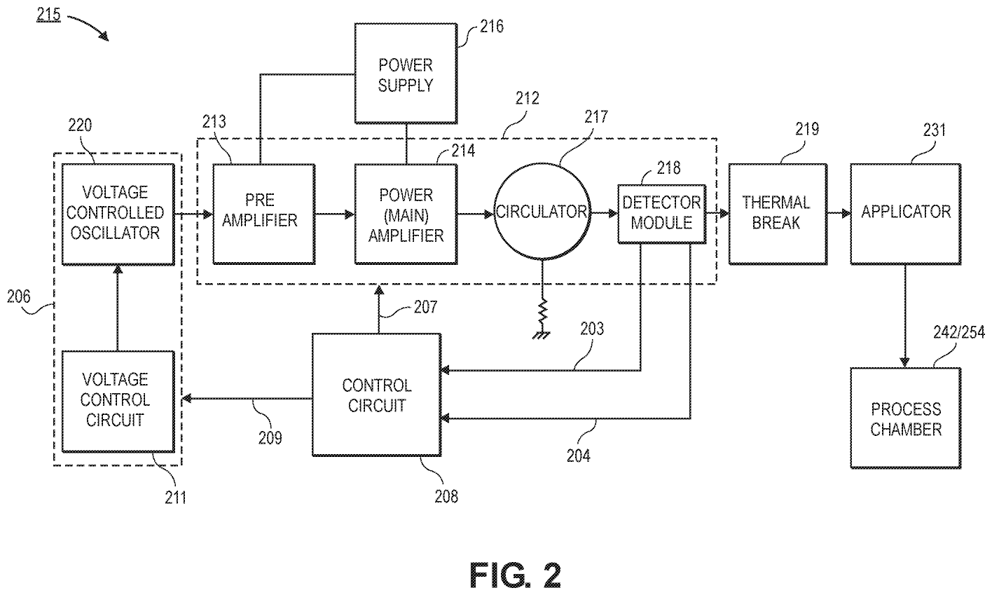

Referring now to FIG. 2, a schematic of a solid state power source 215 is shown, in accordance with an embodiment. In an embodiment, the solid state power source 215 comprises an oscillator module 206. The oscillator module 206 may include a voltage control circuit 211 for providing an input voltage to a voltage controlled oscillator 220 in order to produce microwave electromagnetic radiation at a desired frequency. Embodiments may include an input voltage between approximately 1V and 10V DC. The voltage controlled oscillator 220 is an electronic oscillator whose oscillation frequency is controlled by the input voltage. According to an embodiment, the input voltage from the voltage control circuit 211 results in the voltage controlled oscillator 220 oscillating at a desired frequency. In an embodiment, the microwave electromagnetic radiation may have a frequency between approximately 0.1 MHz and 30 MHz. In an embodiment, the microwave electromagnetic radiation may have a frequency between approximately 30 MHz and 300 MHz. In an embodiment, the microwave electromagnetic radiation may have a frequency between approximately 300 MHz and 1 GHz. In an embodiment, microwave electromagnetic radiation may have a frequency between approximately 1 GHz and 300 GHz.

According to an embodiment, the electromagnetic radiation is transmitted from the voltage controlled oscillator 220 to an amplification module 212. The amplification module 212 may include a driver/pre-amplifier 213, and a main power amplifier 214 that are each coupled to a power supply 216. According to an embodiment, the amplification module 212 may operate in a pulse mode. For example, the amplification module 212 may have a duty cycle between 1% and 99%. In a more particular embodiment, the amplification module 212 may have a duty cycle between approximately 15% and 50%.

In an embodiment, the electromagnetic radiation may be transmitted to a thermal break 219 and the applicator 231 after being processed by the amplification module 212. However, part of the power transmitted to the thermal break 219 may be reflected back due to the mismatch in the output impedance. Accordingly, some embodiments include a detector module 218 that allows for the level of forward power 204 and reflected power 203 to be sensed and fed back to a control circuit module 208 before the reflected power reaches a circulator 217 that routs the reflected power to ground. It is to be appreciated that the detector module 218 may be located at one or more different locations in the system. In an embodiment, the control circuit module 208 interprets the forward power 204 and the reflected power 203, and determines the level for the control signal 209 that is communicatively coupled to the oscillator module 206 and the level for the control signal 207 that is communicatively coupled to the amplifier module 212. In an embodiment, control signal 209 adjusts the oscillator module 206 to optimize the high-frequency radiation coupled to the amplification module 212. In an embodiment, control signal 207 adjusts the amplifier module 212 to optimize the output power coupled to the applicator 231 through the thermal break 219. In an embodiment, the feedback control of the oscillator module 206 and the amplification module 212, in addition to the tailoring of the impedance matching in the thermal break 219 may allow for the level of the reflected power to be less than approximately 5% of the forward power. In some embodiments, the feedback control of the oscillator module 206 and the amplification module 212 may allow for the level of the reflected power to be less than approximately 2% of the forward power.

Accordingly, embodiments allow for an increased percentage of the forward power to be coupled into the processing chamber 242 or cleaning chamber 254, and increases the available power coupled to the plasma. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

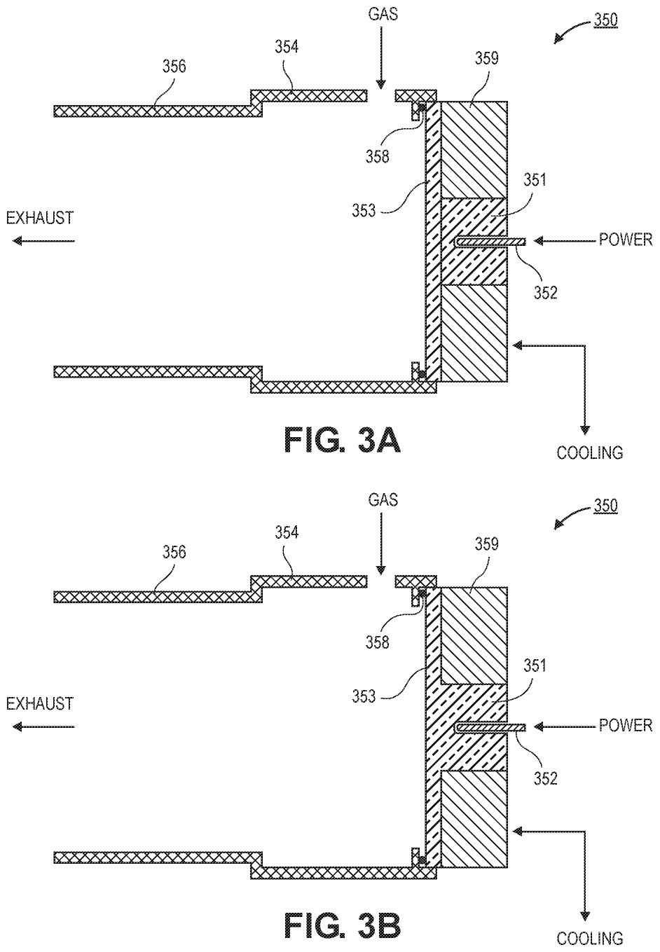

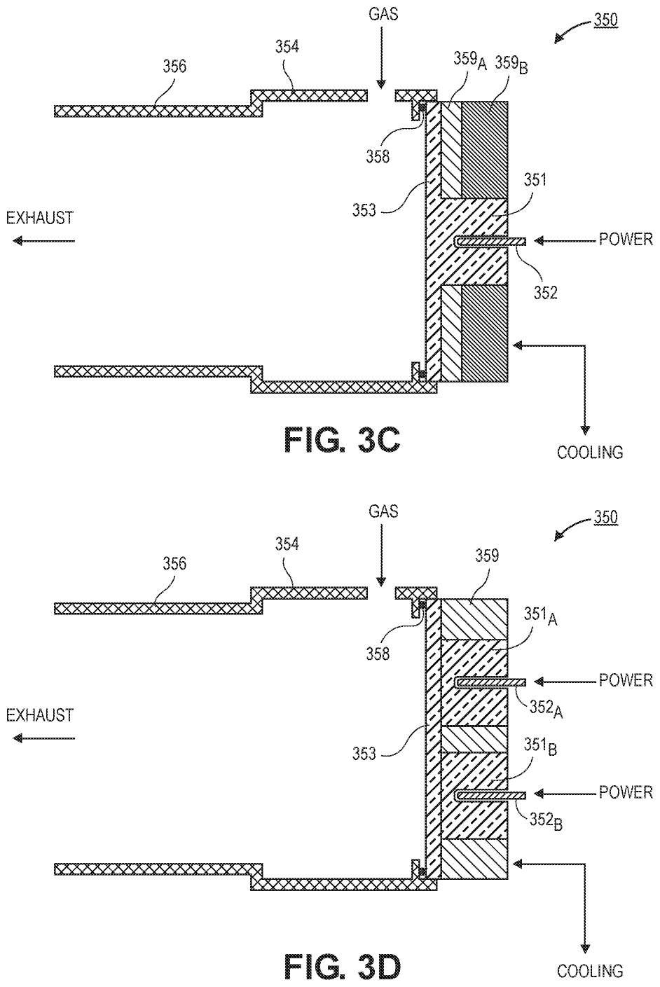

Referring now to FIGS. 3A-3D, cross-sectional illustrations of various plasma cleaning modules 350 are shown, in accordance with various embodiments. The plasma cleaning modules 350 in FIGS. 3A-3D may be integrated with a processing tool. In other embodiments, the plasma cleaning modules 350 may be portable plasma cleaning modules. That is, the plasma cleaning modules 350 may be easily detachable from the processing tool. Portable plasma cleaning modules are described in greater detail below.

Referring now to FIG. 3A, a cross-sectional illustration of a plasma cleaning module 350 is shown, in accordance with an embodiment. The plasma cleaning module 350 may comprise a cleaning chamber 354 in which a plasma is generated. The cleaning chamber 354 may have a first opening and a second opening. The first opening may be closed by a dielectric plate 353. In an embodiment, a seal 358 (e.g., an O-ring or the like) may be positioned between the dielectric plate 353 and the cleaning chamber 354. The second opening may be fluidically coupled to a cleaning line 356. The cleaning line is coupled to an exhaust line of the processing tool (not shown).

In an embodiment, a dielectric resonator 351 is coupled to the dielectric plate 353. A hole may be disposed in an axial center of the dielectric resonator 351. In an embodiment, a monopole antenna 352 is inserted into the hole. The monopole antenna 352 is connected to a power source that supplies microwave electromagnetic radiation. For example, the power source may be a solid state microwave electronics module, such as the solid state power source 215 described above with respect to FIG. 2. In the illustrated embodiment, the dielectric resonator 351 is against an outer surface of the dielectric plate 353. However, in other embodiments, the dielectric resonator 351 may extend through the dielectric plate and extend into the free space within cleaning chamber 354.

In an embodiment, a conductive layer 359 may surround the dielectric resonator 351. The conductive layer 359 may be held at a ground potential in some embodiments. The conductive layer 359 shields the dielectric resonator 351 and provides improved coupling of the microwave electromagnetic radiation into the cleaning chamber 354. In an embodiment, the conductive layer 359 may be a temperature controlled component. For example, the conductive layer may be fluidically coupled to a coolant source. The conductive layer 359 may include cooling channels (not shown) through which coolant from the coolant source flows. In other embodiments, the plasma cleaning module may also include a heating element or be coupled to a source of high temperature thermal fluid.

In an embodiment, gas may be supplied to the cleaning chamber 354. The gas may be injected through a port in a wall of the cleaning chamber 354. In other embodiments, the gas may be supplied to the cleaning chamber 354 through the dielectric plate 353.

Referring now to FIG. 3B, a cross-sectional illustration of a plasma cleaning module 350 is shown, in accordance with an additional embodiment. The plasma cleaning module 350 in FIG. 3B may be substantially similar to the plasma cleaning module 350 in FIG. 3A, with the exception of the interface between the dielectric plate 353 and the dielectric resonator 351. For example, there may be no discernable interface between the dielectric plate 353 and the dielectric resonator 351 in the embodiment shown in FIG. 3B. That is, the dielectric plate 353 and the dielectric resonator 351 may be formed as a single monolithic structure.

Referring now to FIG. 3C, a cross-sectional illustration of a plasma cleaning module 350 is shown, in accordance with an additional embodiment. The plasma cleaning module 350 in FIG. 3C may be substantially similar to the plasma cleaning module 350 in FIG. 3B, with the exception of the construction of the conductive layer 359. As shown, the conductive layer 359 may comprise a plurality of conductive layers. For example, a first conductive layer 359A is over the dielectric plate 353, and a second conductive layer 359B is over the first conductive layer. A similar multi-layer conductive layer 359 may be implemented with a construction similar to the construction shown in FIG. 3A. That is, a first conductive layer 359A and a second conductive layer 359B may be implemented when the dielectric plate 353 and the dielectric resonator 351 are discrete components.

In an embodiment, the first conductive layer 359A may have a first coefficient of thermal expansion (CTE), and the second conductive layer 359B may have a second CTE that is greater than the first CTE. Particularly, the first CTE of the first conductive layer 359A may be closely matched to a CTE of the dielectric plate 353 in order to minimize thermal stresses that may otherwise damage the dielectric plate 353. In a particular embodiment, the first conductive layer 359A may comprise titanium, and the second conductive layer 359B may comprise aluminum. The first conductive layer 359A may be secured to the second conductive layer 359B in some embodiments. For example, the first conductive layer 359A may be bolted or otherwise bonded to the second conductive layer 359B.

Referring now to FIG. 3D, a cross-sectional illustration of a plasma cleaning module 350 is shown, in accordance with an additional embodiment. The plasma cleaning module 350 in FIG. 3D may be substantially similar to the plasma cleaning module 350 in FIG. 3A, with the exception that a plurality of dielectric resonators 351 are disposed over the dielectric plate 353. While two dielectric resonators 351A and 351B are shown, it is to be appreciated that any number of dielectric resonators 351 may be included in the plasma cleaning module 350. Increasing the number of dielectric resonators 351 may provide improved cleaning of the exhaust region.

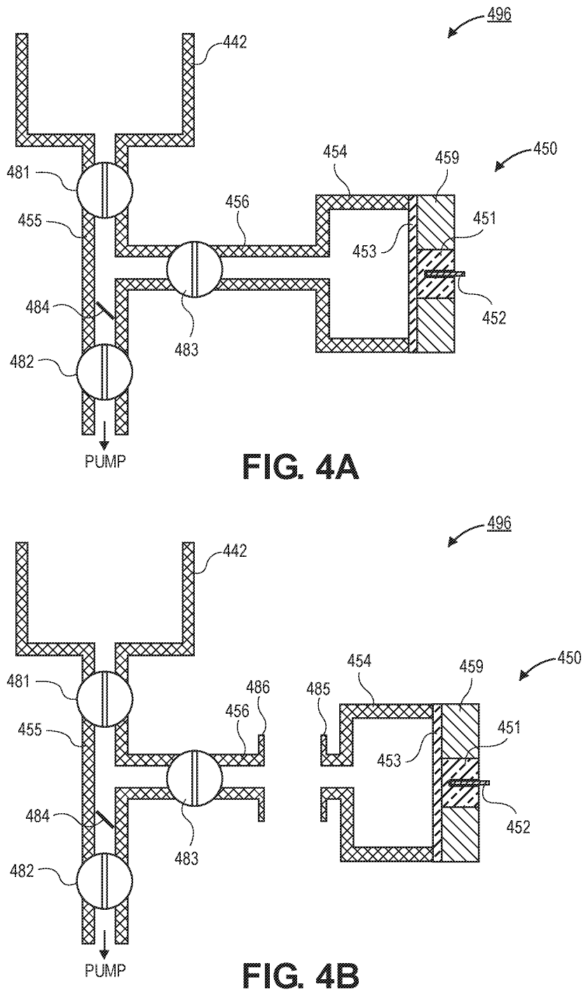

Referring now to FIG. 4A, a cross-sectional illustration of an exhaust region 496 is shown, in accordance with an embodiment. The exhaust region 496 in FIG. 4A illustrates an integrated plasma cleaning module 450. That is, the plasma cleaning module 450 is integrated as part of the processing tool. In an embodiment, the exhaust region 496 comprises an exhaust line 455 that fluidically couples a main processing chamber 442 to a pump. In an embodiment, a throttle valve 484 may be disposed within the exhaust line 455. The cleaning line 456 fluidically couples the cleaning chamber 454 of the plasma cleaning module 450 to the exhaust line 455.

In an embodiment, the plasma cleaning module 450 may be substantially similar to any of the plasma cleaning modules 350 described above. For example, the plasma cleaning module 450 may comprise a cleaning chamber 454, a dielectric plate 453, a dielectric resonator 451, a monopole antenna 452, and a conductive layer 459.

In an embodiment, the exhaust region 496 may comprise a plurality of valves. A first valve 481 may be positioned along the exhaust line 455 between the main chamber 442 and the throttle valve 484. The first valve 481 may be closed to isolate chamber 443 during cleaning. As such, the condition of the main chamber 442 is not changed during or after maintenance. A second valve 482 may be positioned along the exhaust line 455 between the throttle valve 482 and the pump. A third valve 483 may be positioned along the cleaning line 456 between the cleaning chamber 454 and the exhaust line 455. The valves 481, 482, and 483 may be controlled by a processing tool computer (not shown).

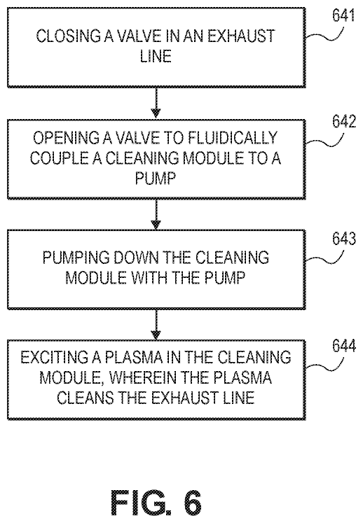

In an embodiment, the valves 481, 482, and 483 may be opened or closed depending on the desire processing operation. For example, during processing of substrates in the main chamber 442, the first valve 481 and the second valve 482 may be opened, and the third valve 483 may be closed. During a cleaning operation, the third valve 483 may be opened and the first valve 481 may be closed. A process for implementing a cleaning operation using the plasma cleaning module 450 is described in greater detail below with respect to FIG. 6.

Referring now to FIG. 4B, a cross-sectional illustration of an exhaust region 496 of a processing tool is shown, in accordance with an additional embodiment. In an embodiment, the exhaust region 496 in FIG. 4B may be substantially similar to the exhaust region 496 in FIG. 4A, with the exception that the plasma cleaning module 450 is a portable plasma cleaning module 450. That is, the plasma cleaning module 450 is configured to be easily attached and detached from the processing tool. In an embodiment, the portable plasma cleaning module may be stored on a cart (described in greater detail below) when not being used.

In an embodiment, the plasma cleaning module 450 may comprise a flange 485 that is attached to the cleaning chamber 454. The cleaning line 456 may also comprise a flange 486 for interfacing with the flange 485 of the plasma cleaning module 450. Any suitable flanges or other connection schemes suitable for providing a vacuum tight seal between the cleaning line 456 and the plasma cleaning module 450 may be used. For example, the flanges 485 and 486 may comprise KF40 or KF50 flanges.

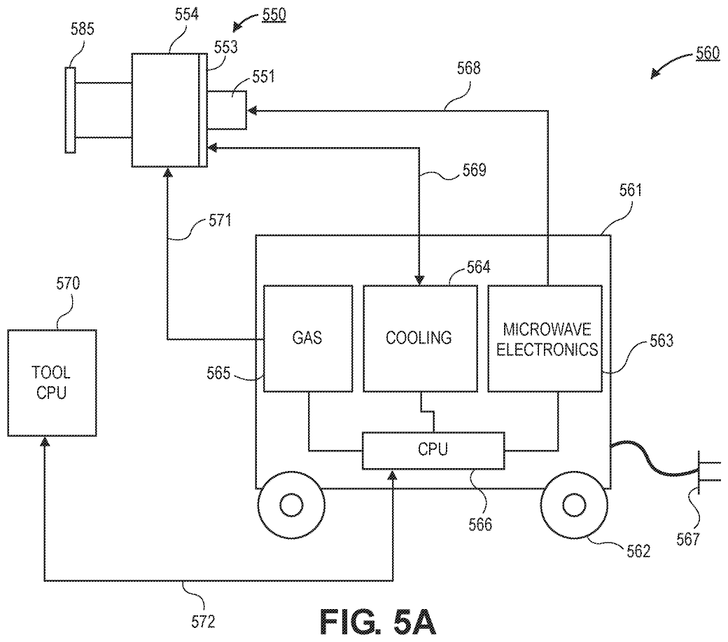

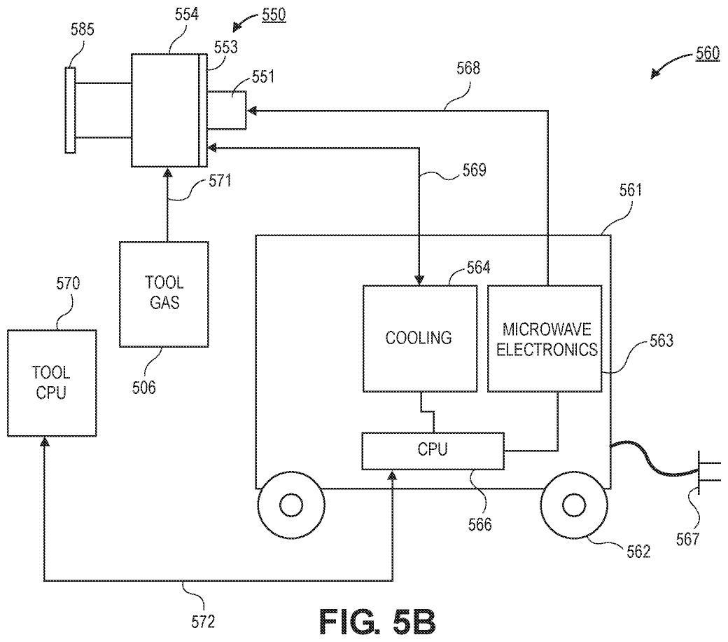

Referring now to FIGS. 5A and 5B, schematics of mobile cleaning assemblies 560 are shown, in accordance with an embodiment. The mobile cleaning assemblies 560 allow for easy movement of the portable plasma cleaning module 550 throughout a facility in order to provide cleaning to a plurality of processing tools. In some embodiments, the mobile cleaning assemblies 560 may also comprise one or more peripherals for the portable plasma cleaning module 550 (e.g., gas, cooling fluid, etc.)

Referring now to FIG. 5A, a schematic of a mobile cleaning assembly 560 is shown, in accordance with an embodiment. In an embodiment, the mobile cleaning assembly 560 comprises a cart 561 and a plasma cleaning module 550 attached to the cart 561. In an embodiment, the plasma cleaning module 550 may be similar to any of the plasma cleaning modules disclosed herein. For example, the plasma cleaning module 550 may comprise a cleaning chamber 554, a dielectric plate 553, and a dielectric resonator 551. A flange 585 or other interconnect component may be connected to the cleaning chamber 554 in order to attach the plasma cleaning module to a processing tool. The cart 561 is easily transferred about a facility. For example, the cart 561 may have a set of wheels 562.

When not in use, the plasma cleaning module 550 is stored on the cart 560. When in use, the plasma cleaning module 550 may be tethered to the cart 560 by various interconnects to peripherals stored on the cart 560. For example, the cart 560 may house solid state microwave electronics 563, a temperature controlled container of heat transfer fluid (e.g., cooling unit 564), and a gas panel 565. The line 568 between the plasma cleaning module 550 and the microwave electronics 563 may be a coaxial cable. The gas line 571 and the fluid line 569 may be any suitable lines for transporting gasses and fluids, respectively.

In yet another embodiment, the plasma cleaning module 550 may be integrated with the processing tool instead of being stored on the cart 560, similar to the embodiment shown in FIG. 4A. In such an embodiment, the peripherals stored on the cart 560 may be attached to the plasma cleaning module 550 by lines 568, 569, and 571 that are detachable from the plasma cleaning module 550 when the plasma cleaning module 550 is not being used.

In an embodiment, a processor (e.g., CPU) 566 is also provided on the cart 561. The processor 566 may be communicatively coupled to the peripherals on the cart 561. As such, the processor 566 may be used to control the plasma cleaning module 550 (i.e., through the control of the microwave electronics 563), as well as the temperature of the plasma cleaning module 550 (i.e., through control of the cooling unit 564) and gas flows to the plasma cleaning module 550 (i.e., through control of the gas panel 565). In some embodiments, the processor 566 may also be communicatively coupled to a processing tool CPU 570. As such, components of the processing tool (not shown) may also be controlled to work in unison with the plasma cleaning module 550. For example, one or more valves in the exhaust region of the processing tool may be opened or closed to initiate a cleaning process.

In an embodiment, the power for the mobile cleaning assembly 560 may be provided by a plug 567. The plug 567 may be a standard plug that connects to a 120V or 240V outlet. Accordingly, dedicated power supplies in order to provide higher voltages are not necessary in such embodiments. The lower power requirements are attributable to the compact design and solid state electronics that drive one (or several) applicators used to inject microwave electromagnetic radiation into the cleaning chamber 554,

Referring now to FIG. 5B, a schematic of a mobile cleaning assembly 560 is shown, in accordance with an additional embodiment. The mobile cleaning assembly 560 may be substantially similar to the mobile cleaning assembly 560 in FIG. 5A, with the exception that one or more of the peripherals to the plasma cleaning module 550 are removed from the cart 561. Particularly, the embodiment in FIG. 5B shows the removal of a gas panel from the cart 561. Instead, gas to the plasma cleaning module 550 is sourced from a gas panel 506 of the processing tool.

In FIG. 5B, the cooling unit 564 remains on the cart 561. However, it is to be appreciated that the cooling unit 564 may also be removed from the cart 561. In such embodiments, the cooling fluid for the plasma cleaning module 550 may be sourced from the cooling unit of the processing tool. In some embodiments, both the gas panel 565 and the cooling unit 564 may be removed from the cart 561.

In other embodiments, the mobile cleaning assembly 560 may only include the plasma cleaning module 550 and corresponding interconnects (e.g., line 568, 569, and 571) for connecting to the processing tool. In such embodiments, the plasma cleaning module 550 may source power, cooling fluid, and gas from the processing tool. The processor of the processing tool may also control the operation of the plasma cleaning module 550.

Referring now to FIG. 6, a process flow diagram that illustrates a process 640 for cleaning an exhaust region of a processing tool is shown, in accordance with an embodiment. Process 640 may be implemented with either an integrated plasma cleaning module or a portable plasma cleaning module. In the case of a portable plasma cleaning module, process 640 may also include attaching the portable plasma cleaning module to the exhaust line.

In an embodiment, process 640 may include operation 641 which includes closing a chamber valve in an exhaust line. The chamber valve that is closed may be a chamber isolation valve. The chamber isolation valve may be a valve that is between the main chamber and the cleaning line. For example, the valve that is closed may be the first valve 481 shown in FIGS. 4A and 4B. Closing the chamber isolation valve allows for the cleaning process to proceed without altering the pressure of the main chamber. As such, an additional pump down after the maintenance is not needed, and downtime of the processing tool is reduced.

In an embodiment, process 640 may include operation 462 which includes opening a valve to fluidically couple a plasma cleaning module to a pump. For example, the valve that is opened may be the third valve 483 in FIGS. 4A and 4B.

In an embodiment, process 640 may include operation 463 which includes pumping down the plasma cleaning module with the pump. For example, the pump may be activated to create a pressure suitable for plasma generation in a cleaning chamber of the plasma cleaning module.

After the vacuum in the cleaning chamber is provided, process 640 may include operation 646 which includes exciting a plasma in the plasma cleaning module. In an embodiment, the plasma may be referred to as a remote plasma. That is, the plasma may be provided remotely to the location where cleaning is desired. For example, the cleaning may occur in the exhaust line that is attached to the cleaning line and the plasma cleaning module. In an embodiment, the cleaning may include cleaning of a throttle valve that is included in the exhaust line.

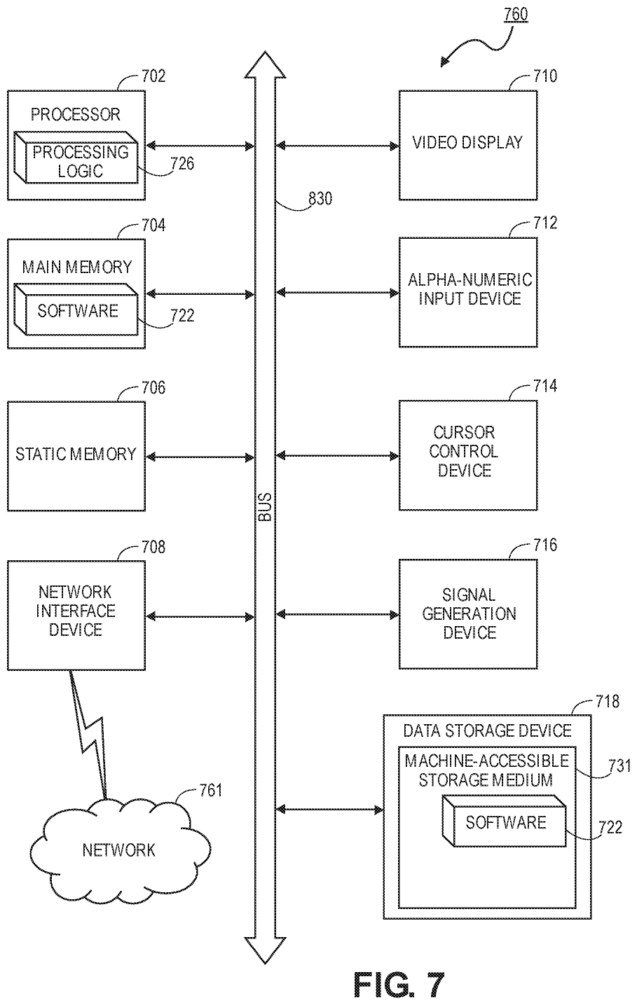

Referring now to FIG. 7, a block diagram of an exemplary computer system 760 of a processing tool or a mobile plasma cleaning module that may be used in accordance with an embodiment is shown. In an embodiment, computer system 760 is coupled to and controls processing in the plasma chamber. Computer system 760 may be connected (e.g., networked) to other machines in a Local Area Network (LAN), an intranet, an extranet, or the Internet. Computer system 760 may operate in the capacity of a server or a client machine in a client-server network environment, or as a peer machine in a peer-to-peer (or distributed) network environment. Computer system 760 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 760, the term “machine” shall also be taken to include any collection of machines (e.g., computers) that individually or jointly execute a set (or multiple sets) of instructions to perform any one or more of the methodologies described herein.

Computer system 760 may include a computer program product, or software 722, having a non-transitory machine-readable medium having stored thereon instructions, which may be used to program computer system 760 (or other electronic devices) to perform a process such as process 550 according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 760 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 760 may further include a system network interface device 708 for communicating with other devices or machines. The computer system 760 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 760, the main memory 704 and the system processor 702 also constituting machine-readable storage media. The software 722 may further be transmitted or received over a network 720 via the system network interface device 708.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A mobile cleaning module, comprising:
a chamber, wherein the chamber comprises a first opening and a second opening; and
a lid to seal the first opening, wherein the lid comprises:
a dielectric plate;
a dielectric resonator coupled to the dielectric plate;
a monopole antenna positioned in a hole into the dielectric resonator; and
a conductive layer surrounding the dielectric resonator.

2. The mobile cleaning module of claim 1, wherein the second opening comprises a flange.

3. The mobile cleaning module of claim 2, wherein the flange is a KF40 flange or a KF50 flange.

4. The mobile cleaning module of claim 1, further comprising:
a port for introducing gas into the chamber.

5. The mobile cleaning module of claim 1, wherein the lid further comprises channels for flowing a coolant.

6. The mobile cleaning module of claim 1, wherein the monopole antenna is electrically coupled to a solid state microwave source.

7. The mobile cleaning module of claim 1, wherein the lid further comprises:
a second dielectric resonator coupled to the dielectric plate; and
a second monopole antenna positioned in a hole in the second dielectric resonator.

8. The mobile cleaning module of claim 1, wherein the dielectric resonator is a discrete body from the dielectric plate.

9. The mobile cleaning module of claim 1, wherein the dielectric resonator and the dielectric plate are a monolithic structure.

10. The mobile cleaning module of claim 1, wherein the conductive layer comprises a first conductive layer adjacent to the dielectric plate and a second conductive layer over the first conductive layer, wherein a coefficient of thermal expansion of the first conductive layer is smaller than a coefficient of thermal expansion of the second conductive layer.

11. A mobile cleaning assembly, comprising:
a cart;
a solid state electronics module on the cart, wherein the solid state electronics module is configured to generate microwave electromagnetic radiation;
a processor on the cart and electrically coupled to the solid state electronics module; and
a plasma cleaning module, wherein the plasma cleaning module is electrically coupled to the solid state electronics module.

12. The mobile cleaning assembly of claim 11, further comprising:
a temperature controlled container on the cart and electrically coupled to the processor, wherein the temperature controlled container is configured to hold a heat transfer fluid, and wherein the plasma cleaning module is fluidically coupled to the temperature controlled container.

13. The mobile cleaning assembly of claim 11, further comprising:
a gas panel on the cart and electrically coupled to the processor, wherein the plasma cleaning module is fluidically coupled to the gas panel.

14. The mobile cleaning assembly of claim 11, wherein power is supplied to the cart by a 120V or a 240V outlet.

15. The mobile cleaning assembly of claim 11, wherein the plasma cleaning module comprises:
a chamber, wherein the chamber comprises a first opening and a second opening; and
a lid to seal the first opening, wherein the lid comprises:
a dielectric plate;
a dielectric resonator coupled to the dielectric plate;
a monopole antenna positioned in a hole into the dielectric resonator; and
a conductive layer surrounding the dielectric resonator.

16. The mobile cleaning assembly of claim 15, wherein the second opening comprises a flange.

17. A plasma processing tool, comprising:
a first chamber with a pedestal for supporting a substrate;
an exhaust line fluidically coupled to the first chamber, wherein the exhaust line comprises:
a pump;
a main exhaust line between the first chamber and the pump;
a throttle valve positioned in the main exhaust line;
a cleaning line fluidically coupled to the main exhaust line;
a second chamber fluidically coupled to the cleaning line; and
a plasma source for generating a plasma in the second chamber.

18. The plasma processing tool of claim 17, wherein the second chamber is removably coupled to the cleaning line.

19. The plasma processing tool of claim 17, further comprising:
a first valve between the throttle valve and the pump; and
a second valve between the second chamber and the cleaning line.

20. The plasma processing tool of claim 19, further comprising:
a third valve between the first chamber and the throttle valve.
